(19) United States
(12) Patent Application Publication
(10) Pub. No.: US 2005/0092248 A1
(43) Pub. Date: May 5, 2005

(54) Chemical vapor deposition unit

(75) Inventors: Kyeong-Ha Lee, Seongnam-Si (KR); Sang-Chul Kim, Daejeon (KR); Do-Il Jung, Daejeon (KR); Hyun-Soo Park, Daejeon (KR)

Correspondence Address: Peter T. Kwon;GWiPS, Kangnam, P.O. Box 2301, Seoul, 135-242, KR

(73) Assignee: SYSNEX Co., Ltd.

(21) Appl. No.: 10/977,943

(22) Filed: Oct. 18, 2004

(30) Foreign Application Priority Data
Oct. 31, 2003 (KR) 2003-0076799

(51) Int. Cl. C23C 16/00

(52) U.S. Cl. 118/715

(57) ABSTRACT

A chemical vapor deposition unit is invented for forming a uniform thin film over the entire surface of a substrat by the vapor-deposition. The chemical vapor deposition unit comprises a reaction chamber isolated from the outside and kept under vacuum, a susceptor, on which at least one substrate is placed, installed in the reaction chamber such that it can rotate, and an injector, including independently formed first and second gas passages, and first and second gas injecting pipes that communicate with the respective gas passages and respective outlets, for injecting respective first and second gases onto the susceptor, the injector injecting the different gases independently. The injector further comprises a gas injecting part for communicating with the second gas passage so that only the second gas, which is a non-reactive carrier gas, is injected in a central region of the susceptor.

### BACKGROUND OF THE INVENTION

1. Field of the Invention

The present invention relates to a chemical vapor deposition unit, and more particularly to a chemical vapor deposition unit for forming a uniform thin film over the entire surface of a substrate by providing a smooth flow of various kinds of gases to deposit a thin film on a substrate.

2. Description of the Related Art

Generally, semiconductors are manufactured by the process of constructing electric circuits, repeatedly performing a diffusion process, a photographing process, an etching process, and a thin film process on a raw material of substrate.

The thin film process, among the manufacturing processes for the semiconductor, is a process of vapor-depositing a thin film on a substrate to a desired thickness. Among the vapor deposition methods, there are chemical vapor deposition, ion injection, metal vapor deposition, and the like.

Metal organic chemical vapor deposition, one of the chemical vapor deposition methods, is a method of forming a thin film on a heated substrate using pyrolysis and re-reaction. In metal organic chemical vapor deposition, a group III element gas and ammonia gas are injected into a reactor and undergo pyrolysis and chemical reactions, so that a nitride thin film is grown on the substrate. Metal organic chemical vapor deposition is widely used because of its ability to easily create the grown layer and its low maintenance, low price, and specific and precise controllability.

As shown in FIG. 1, a conventional chemical vapor deposition unit includes an isolated reaction chamber (10) kept under vacuum, a susceptor (20) installed in the reaction chamber (10), on which a substrate P is placed, and a gas injector (30) for injecting different gases to form a thin film on the substrate (P) placed on the susceptor (20).

The gas injector (30), for example, includes a first gas injecting pipe (31) for injecting a first gas (G1), a second gas injecting pipe (32) for injecting a second gas (G2), and a plenum which is divided into independent passages, such as a first gas passage (36), a second gas passage (37), and a coolant passage (38), by horizontal partitions (33, 34, 35) from the upper side as seen in the drawing.

In order to inject the first and second gases (G1, G2) along the respective passages (36, 37), the tubular first and second gas injecting pipes (31, 32) differ in length. The partition (33) is installed between the entrances of the first and second gas injecting pipes (31, 32) so as to divide the plenum into the first gas passage (36) on the upper side and the second gas passage (37) on the lower side.

An injecting surface (35a) at the discharge of the first and second gas injecting pipes (31, 32), and the surface of the susceptor (20) are flat and they are positioned so as to have a uniform gap there-between.

The coolant passage (38) is disposed below the second gas passage (370), and the gas injecting pipes (31, 32) penetrate the coolant passage (38).

According to the conventional chemical vapor deposition unit, the first and second gases (G1, G2) flow through the gas passages (36, 37), respectively, separated by the first partition (33), and are injected onto the substrate (P), which is being rotated by the susceptor (20) through the first and second gas injecting pipes (31, 32). Simultaneously, the substrate (P) is heated, and the first and second gases (G1, G2) undergo pyrolysis and are re-reacted, so that the thin film is formed on the substrate (P). On the other hand, the coolant flowing through the coolant passage (380) regulates the temperature of the injector (30).

As described above, since chemical vapor deposition grows the thin film on the substrate (P) in the manner that the first and second gases (G1, G2) undergo pyrolysis over the heated susceptor (20) and are re-reacted with each other on the substrate (P), the flow rate, density, and temperature of the gas are closely related.

Moreover, in the growth of the thin film, the gas exhibits a laminar flow, the growth rate of the thin film increases as the flow rates of the reactive gases increase and as the densities (mixture ratios) of the reactive gases become greater.

Since the above-mentioned factors must be controlled, the conventional chemical vapor deposition unit has disadvantage as follows:

Since the clearance and the overall surface level between the gas injecting surface (35a) and the susceptor (20), and the amount of injected gases (G1, G2) per unit surface are constant from the gas injecting surface (35a), the deposited thickness of thin film will not be uniform because the density of the first gas (G1) is decreasing along the substrate (P). The central region (21) of the susceptor (20), which is near the injecting clearance is deposited more gases than the farther of the substrate so that the thickness is forming thinner along the substrate (P).

If the susceptor (20) is rotated in an attempt to provide a uniform thickness, the relative velocity at the central region of the susceptor (20) is slower than the relative velocity at the outer region of the susceptor (20). The difference between the relative velocities is proportional to the revolutions per minute of the susceptor (20). By carefully choosing the rotational rate of the susceptor (20), the growth rate of the thin film on the substrate (P) near the central region (21) can be adjusted to be similar to the growth rate on the substrate (P) facing the outer region of the susceptor (20), so that uniform thickness can be obtained. However, the portions of the first and second gases (G1, G2) that are injected from the central region of the gas-injecting surface (35a) react at the central region (21) where there is no substrate (P), so that by-products are generated. The by-products pass over the substrate (P) placed on the susceptor (20), together with the gas flow. The by-products interfere with the deposition on the substrate (P), and as a result, the uniform thickness and quality of the thin film are deteriorated so that a poor quality of semiconductor device may be produced.

In contrast, the present invention can eliminate the by-products at the central region (21) of the susceptor (20) by using a showerhead (See FIGS. 2 and 3) for injecting only the second gas at the central region (21).

Moreover, since the susceptor (20) must be rotated during heating thereof, it is difficult to directly heat the central region (21) of the susceptor (20). Although the susceptor (20) is being heated by the heat conductivity of the susceptor materials, the temperature of the central region (21) is lower than that of the outer region thereof. In other words, it is difficult to perform the thin film vapor deposition on the substrate (P) over the central region (21) of the susceptor (20). As s result, the reactive gas is wasted.

Therefore, the conditions under which the conventional gas injector for chemical vapor deposition can obtain a uniform thin film can be optimized by adjusting the density of the injected gas and the revolutions per minute of the susceptor (20). However, there is a limit to which the uniformity of the thickness and quality of the thin film can be optimized, due to the presence of by-products at the central region. Further, when, for the purpose of enhancing productivity of the high quality thin film, the thin film is grown on tens of substrates (P) in a single process, uniform thin films may be obtained. However, since the by-products are increased as the amount of gas is increased, it is almost impossible to achieve high productivity and high quality of the semiconductor.

In contrast, a gas injector according to the present invention injects only one gas from a central portion thereof so as to remove the by-products generated at the central region of the susceptor (20). Thus, a high quality thin film can be obtained.

Moreover, since the gas injecting surface (34) and the opposite surface of the susceptor (20) are flat plane in the conventional art, the gas injected toward the right central region of the susceptor (20) exhibits a stagnated flow. For this reason, the reactive gases on the substrate are interfered with and do not exhibit a laminar flow, so that the reacted gases are not deposited on the substrate (P). In contrast, the gas injector (See FIG. 4) and the susceptor (See FIG. 5) of the present invention minimize the stagnated flow at the central region of the susceptor, so that the gas flow can be enhanced over the entire region of the susceptor (20).

FIGS. 7a and 7b illustrate the thickness and wavelength PL data of the thin film vapor-deposited by the conventional chemical vapor deposition unit. In the drawings, the average thickness of the thin film is 3.057 μm, the minimum thickness is 2.991 μm, and the maximum thickness is 3.302 μm, thus there is a great variation in the thickness. Meanwhile, the standard deviation of the thickness is 2.11%, which is too high for the production of commercial thin films. When seeing the wavelength data, the minimum wavelength is 477.7 nm, the maximum wavelength is 492.0 nm, and the standard deviation of the wavelength is 3.671 nm. Since the thickness is not uniform over the whole substrate, the wavelength is also not uniform and the thickness of the thin film does not satisfy the requirements of commercial thin films.

### SUMMARY OF THE INVENTION

Therefore, the present invention has been made in view of the above problems, and it is an object of the present invention to provide a chemical vapor deposition unit having a gas injector for injecting a single gas from a central portion thereof so as to remove by-products generated at the central region of a susceptor and to enhance the uniformity of thickness and quality of the thin film.

It is another object of the present invention to provide a chemical vapor deposition unit capable of enhancing the uniformity of thickness of the thin film by reducing the difference between densities of gases (ratio of the mixture) over the entire region of a substrate by injecting reactive gases only on the substrate.

It is yet another object of the present invention to provide a chemical vapor deposition unit capable of obtaining laminar flow of the gas over the entire region of a susceptor by removing the stagnated flow generated at regions where reaction is unnecessary, that is, a region extending from the central region of a gas injector of the chemical vapor deposition unit to the central region of the susceptor.

In accordance with an object of the present invention, the above and other objects can be accomplished by the provision of a chemical vapor deposition unit including a reaction chamber isolated from the outside and kept under vacuum, a susceptor installed in the reacting chamber which can rotate and on which at least one substrate is placed, and an injector, including independently formed first and second gas passages, and first and second gas injecting pipes that communicate with the respective gas passages at respective inlets, for injecting respective first and second gases onto the susceptor, the injector injecting the different gases independently, wherein a portion, corresponding to a central region of the susceptor, is installed with only the second gas injecting pipe so that only the second of the two gases, which is a non-reactive carrier gas, is injected in the central region of the susceptor.

In accordance with another object of the present invention, there is provided a chemical vapor deposition unit including a reaction chamber isolated from the outside and kept under vacuum, a susceptor, on which at least one substrate is placed, installed in the reaction chamber such that it can rotate, and an injector, including independently formed first and second gas passages, and first and second gas injecting pipes that communicate with the respective gas passages at respective inlets, for injecting respective first and second gases onto the susceptor, the injector injecting the different gases independently, wherein the injector further includes a gas injecting part communicating with the second gas passage so that only the second of the two gases, which is a non-reactive carrier gas, is injected in a central region of the susceptor.

Preferably, a second gas region having a cross-sectional area greater than that of the other region may be further formed between the second gas passage and the gas injecting part.

### BRIEF DESCRIPTION OF THE DRAWINGS

These and/or other objects and advantages of the present invention will become apparent and more readily appreciated from the following description of the embodiments, taken in conjunction with the accompanying drawings, in which:

FIG. 1 is a schematic view illustrating a convention chemical vapor deposition unit;

FIG. 2 is a schematic structural view illustrating a chemical vapor deposition unit according to a first embodiment of the present invention;

FIG. 3 is a schematic structural view illustrating a chemical vapor deposition unit according to a second embodiment of the present invention;

FIG. 4 is a schematic structural view illustrating a chemical vapor deposition unit according to a third embodiment of the present invention;

FIG. 5 is a schematic structural view illustrating a chemical vapor deposition unit according to a fourth embodiment of the present invention;

FIGS. 6a and 6b are diagrams illustrating the thickness and wavelength PL data of a thin film grown on the substrate by the chemical vapor deposition unit according to the respective embodiments of the present invention; and

FIGS. 7a and 7b are diagrams illustrating the thickness and wavelength PL data of a thin film grown on the substrate by the conventional chemical vapor deposition unit.

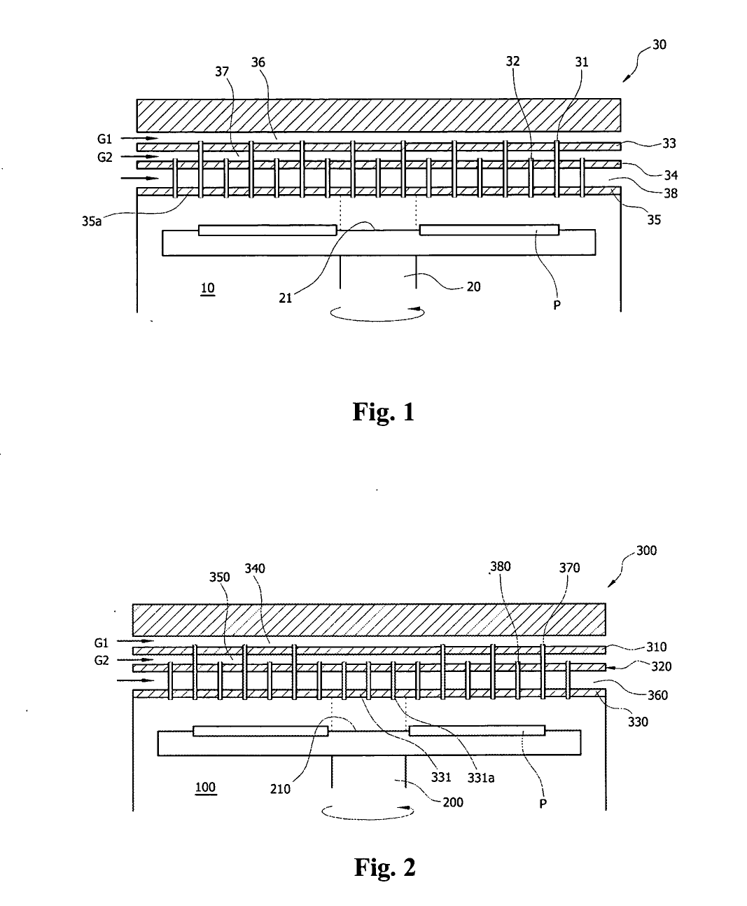

### DESCRIPTION OF THE PREFERRED EMBODIMENTS

The present invention is characterized in that different gases for forming a thin film on a substrate can form a uniform thin film regardless of where the substrate is placed on the susceptor, and quality of products can be enhanced. The conditions, which must be satisfied in order to achieve the present invention, are enumerated below.

(1) There must be no by-products generated by the reaction between a first gas and a second gas at the central region of the susceptor that can interfere with the vapor deposition on the substrate.

As the capacity and volume of the equipment are increased, the diameter of the susceptor and the number of the substrates used at once are increased. The uniformity of the thin films grown on the plural substrates must be enhanced. Furthermore, the quality of a substrate placed on the central region of the susceptor must not be different from the quality of a substrate placed on the outer region of the susceptor. This means that to remove the by-products from the central region of the susceptor, where the thin film cannot grow due to the low temperatures caused by structural problems of the susceptor, it is necessary to inject the reactive gases from a region other than the central region of the gas injector. However, if no gas flows through the central region of the susceptor, there is generated a so-called “dead volume” where the gas remains. If the gases injected in the previous process are diffused, for even a few seconds, in a process in which various reactive gases, for example, a dopant gas, must be used, the diffusion affects the subsequent process. If the same reactive gases as the gases injected on the substrate placed on the outer region of the susceptor are injected on the substrate placed on the central region of the susceptor in the conventional manner, productivity and quality of the thin film grown on the central substrate are deteriorated due to the variation of the thickness and formation of by-products.

This problem can be solved by removing the dead volume where the gas remains. In other words, only carrier gas, which does not directly react on the substrate, is allowed to flow over the substrate placed on the central region of the susceptor.

(2) The upright-bent flow due to the rotation of the susceptor is reduced so that gas flow is rapid and laminar flow is smooth.

If different gases are simultaneously injected at the central region of the susceptor and flow out of the susceptor, the different gases collide with the by-products generated by the reaction of the different gases in the stagnant area. Thus, smooth laminar flow of the gases may be interrupted so that a great difference will exist between the thickness of the thin film at the inner region of the substrate and the thickness of the thin film at the outer region of the substrate. This is an important factor because uniformity of thin film thickness determines the quality and productivity of the semiconductor device.

The chemical vapor deposition units according to the embodiments of the present invention, which satisfy the above-described conditions and are capable of forming a uniform thin film on substrates placed on any portion of the susceptor, will be described in great detail.

### EMBODIMENT 1

As shown in FIG. 2, a chemical vapor deposition unit according to a first embodiment of the present invention comprises a reaction chamber (100), which is isolated from the outside and kept under vacuum, a susceptor (200) installed in the reaction chamber (100), where at least one substrate (P) is placed, and a gas injector (300) for injecting different gases to form a thin film on the substrate (P) placed on the susceptor (200).

The gas injector (300) includes a first gas passage (340), a second gas passage (350), and a coolant passage (360) independently formed by partitions (310, 320, 330), disposed in turn from top to bottom as seen in the drawing, a first gas injecting pipe (370) for injecting a first gas (G1), and a second gas injecting pipe (380) for injecting a second gas (G2).

In order to allow the first and second gases (G1, G2) to be injected along the respective passages (340, 350), the tubular first and second gas injecting pipes (370, 380) have different respective lengths, and their upper inlets correspond to the first and second gas passages (340, 350).

In this embodiment, in order to inject only the second gas (G2) in the central region (210) of the susceptor (200), a region corresponding to the central region (210) is installed with only the second gas-injecting pipe (380). In other words, the first gas-injecting pipe (370) is installed in all regions except the central region (210) of the susceptor (200).

The operation of the chemical vapor deposition unit according to this embodiment of the present invention is described below.

The first gas (G1) supplied to the first gas passage (340) is injected onto the susceptor (200) through the first gas injecting pipe (370), and the second gas (G2) supplied to the second gas passage (350) is injected onto the susceptor (200) through the second gas injecting pipe (380). At this time, since the two gases (G1, G2) are separated from each other until passing through the respective gas injecting pipes (370, 380), there is a low possibility that the different gases (G1, G2) may react with each other. The first gas (G1) and the second gas (G2), after passing through the gas injecting pipes (370, 380) respectively, are pyrolysed while passing over the rotating susceptor (200), and are recombined with the pyrolysed atoms, so that the gases (G1, G2) are vapor-deposited on the substrate (P). Meanwhile, the injected gases (G1, G2) pass across the substrate (P) on the rotating susceptor (200). At this time, the first gas (G1) and the second gas (G2) have uniform densities (mixture ratios) over the entire area of the substrate (P) and react with each other, and then exit out the susceptor (200). As a result, a uniform thin film is generated on the substrate (P).

During the process of thin film vapor deposition by the different kinds of gases (G1, G2), since the region corresponding to the central region (210) of the susceptor (200) is installed with only the second gas injecting pipe (380), only the second gas (G2) is present in the central region (210). Therefore, in the central region (210) of the susceptor (200), no reaction between the gases (G1, G2) takes place. The second gas (G2) occupies a space where there is a shortage of the first gas (G1), and meets the first gas (G1) at the outer region of the susceptor (200), while exiting the susceptor (200). At this time, the second gas (G2) reacts with the first gas (G1) and is deposited on the substrate (P). Thus, the gases over the plural substrates (P) placed on the susceptor (200) are not concentrated at one side, but rather are uniformly distributed over the entire area, and there is no reaction at the central region (210) of the susceptor (200).

### EMBODIMENT 2

A chemical vapor deposition unit according to the second embodiment of the present invention has substantially the same structure as that of the first embodiment. However, the manufacturing process in this embodiment is simpler than that of the first embodiment, and the number of joints between the gas injecting pipes and the partitions is also reduced by reducing the number of gas injecting pipes in the central region, as compared to the gas injector shown in FIG. 2. This reduces the number of injectors that must be rejected due to inferior quality.

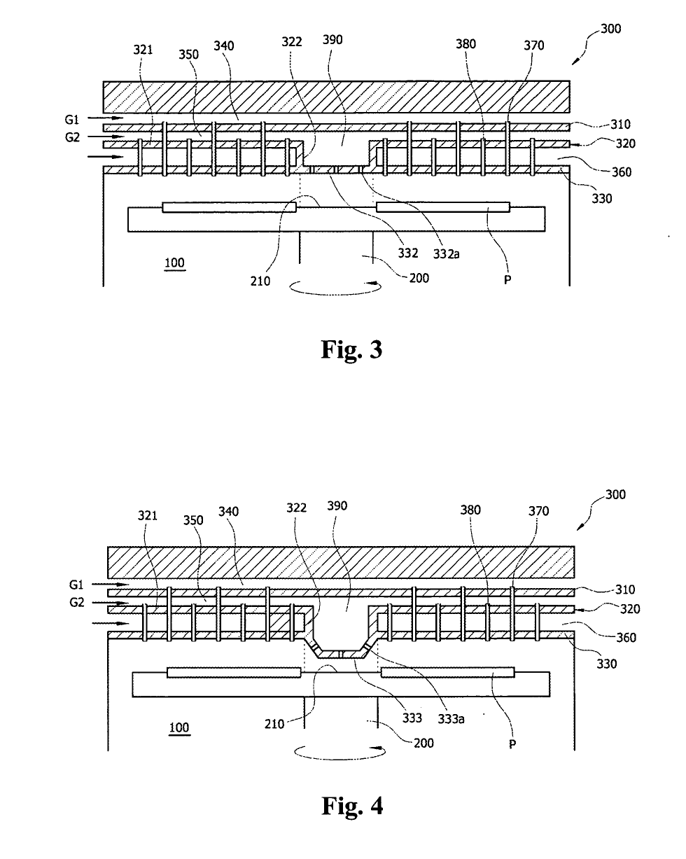

As shown in FIG. 3, in this embodiment, only the second gas (G2) is injected in the central region (210) of the susceptor (200) so that there is no reaction in the central region (210). By doing so, the second partition (320) is cut-out a center hole for providing central space of the second gas passage (350) through the coolant passage (360) to uniformly form the thin film on the substrate (P) disposed over the entirety of the susceptor (200). The size of the central hole on the second partition (320) corresponds to the central region of the susceptor (200) as seen from above. In other words, the second partition (320) having annular disk shape includes a horizontal part (321) and a vertical part (322), while the vertical part (322) is formed at the central portion corresponding to the central region (210) of the susceptor (200). The second partition (320) could be an integral structure that the lower end of the vertical part (322) is integrally connected to the third partition (330).

Thus, the central portion of the third partition (330) which corresponds to the central cut-out portion of the second partition (320) and the central region (210) of the susceptor (200) has the central second gas injecting plate (332) with injecting holes (332a) for injecting only the second gas (G2). The inside of the second partition (320) communicates with the second gas passage (350) and forms with a second gas chamber (390).

During the thin film vapor deposition process using the different gases (G1, G2), the second gas (G2) i.e., part of the carrier gas flows through the injecting hole (332a) of the second gas injecting plate (332) via the second gas region (390). Since the only second gas is injected from the central gas injecting plate (332) to the central region (210) of the susceptor (200), there is no reaction between the two gases (G1, G2). The second gas (G2) injected to the central region (210) of the susceptor (200) is spread to react with the first gas (G1) while flowing over the substrate (P) on the susceptor (200). At this time, the second gas (G2) reacts with the first gas (G1) to be deposited on the substrate (P). Thus, the gases are spread over the plural substrates (P) attached on the susceptor (200) to be uniformly distributed over the entire surface. Because the only one kind of gas is injected at the central region (210), there is no reaction occurred at the central region (210) of the susceptor (200).

### EMBODIMENT 3

As shown in FIG. 4, a chemical vapor deposition unit according to third embodiment of the present invention is substantially the same as that of the chemical vapor deposition unit according to the second embodiment. However, the second gas injecting part (333) has protruded dome or bowl-shape downward the susceptor (200), so that the second gas (G2) injected through the injecting holes (333a) of the second gas injecting part (333) can be smoothly spread over the substrate (P).

According to third embodiment, the second gas (G2) after passing through the second gas chamber (390) is guided to flow toward the circumferential side of the susceptor (200) via the injecting hole (333), formed toward the circumferential side of the susceptor (200). Thus, the dead zone where the reaction does not take place above the susceptor (200) and the upright-bent flow are possibly minimized, so that the gas flow could be improved.

### EMBODIMENT 4

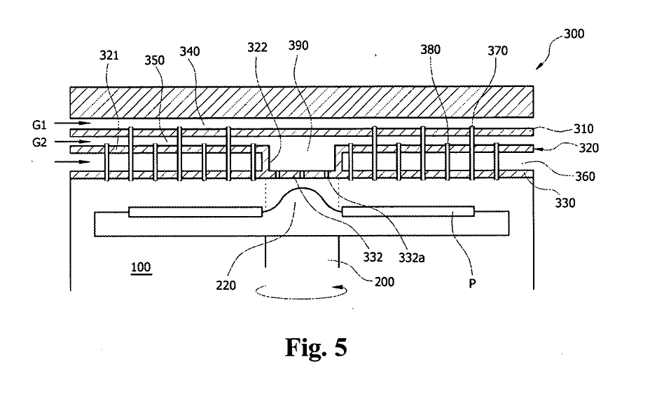

As shown in FIG. 5, a chemical vapor deposition unit according to this embodiment of the present invention is substantially the same as that of the chemical vapor deposition unit according to the second embodiment, and further includes a guide part (220). The guide part (220) is formed in the central region of the susceptor (200) corresponding to the second gas injecting part (332), and guides the flow of the second gas (G2) injected through the second gas injecting part (332).

The guide part (220) serves to eliminate the upright-bent flow of the second gas (G2) injected through the second gas injecting part (332), so that the first and second gases (G1, G2) injected onto the susceptor (200) exhibit laminar flow over the entire area. Although a convex type guide part (220) is seen in FIG. 5, the shape of the guide part (220) is not limited to the convex style, dome shape or any other shape which helps the flow of the second gas (G2) is possible.

In addition, although the guide part (220) of this embodiment has been described only as being applied to the second embodiment, the guide part (220) may be applied to the first and third embodiments by modifying its structure and/or shape.

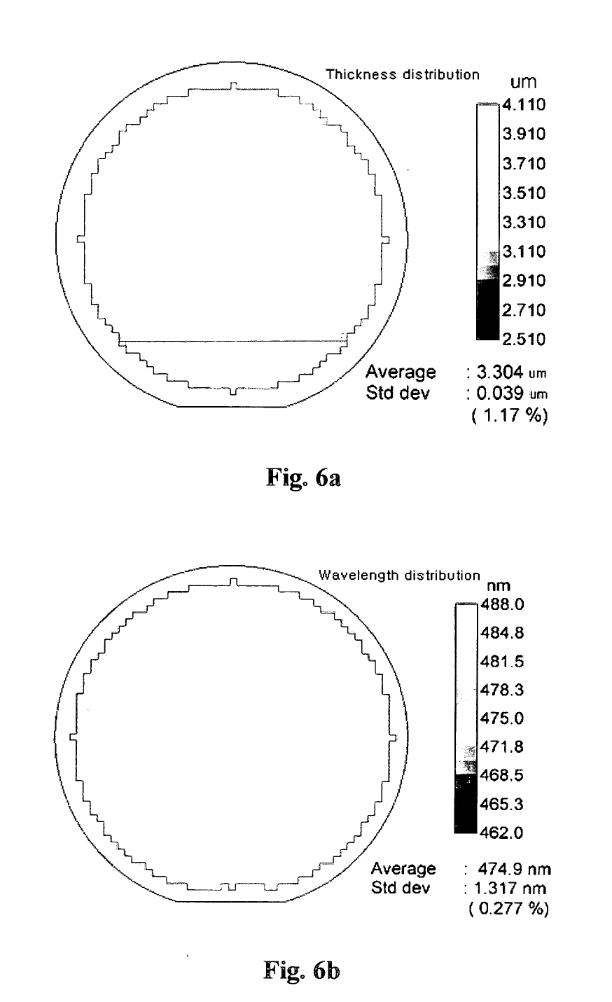

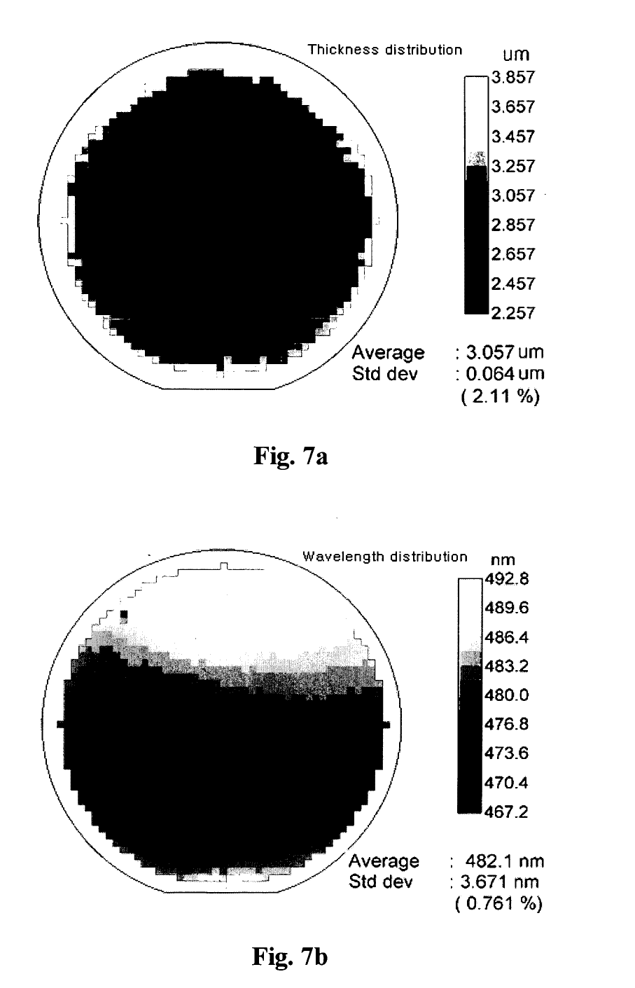

FIGS. 6a and 6b show the thickness and wavelength PL data of the thin film grown on the substrate by the chemical vapor deposition unit according to the respective embodiments of the present invention. In comparison with the thickness of the thin film grown by the conventional chemical vapor deposition unit shown in FIG. 7a, the average thickness of the thin film grown by the chemical vapor deposition unit according to the respective embodiments of the present invention is 3.304 μm, an increase of 8.08%. In comparison with the thickness of the thin film grown by the conventional chemical vapor deposition unit shown in FIG. 7a, the standard deviation of the thickness of the thin film grown by the chemical vapor deposition unit according to the respective embodiments of the present invention is 0.039 μm, an enhancement of 44.5%. The increased growth rate decreases gas consumption for thin films of equal thickness. As seen in the wavelength PL data, the standard deviation of the wavelength in the present invention is 1.317 nm, an enhancement of 64.1% in comparison with the standard deviation of the wavelength of the thin film grown by the conventional chemical vapor deposition unit shown in FIG. 7b. This shows that wavelength is uniform when the thin film is grown uniformly over the entire area of the substrate. In other words, it demonstrates that productivity of the substrate can be enhanced.

As described above, according to the chemical vapor deposition unit of the present invention, the reaction in the central region of the rotating susceptor is restrained, so that the thin film can be uniformly vapor-deposited on substrates disposed over the entire region of the susceptor.

Tables 1 and 2 show the wavelength PL data and the thickness of the thin film grown by the chemical vapor deposition units according to the embodiments of the present invention.

TABLE 1

| | Conventional | Present | Enhancement |
|---|---|---|---|
| | unit | invention | (%) |
| Average | 3.057 | 3.304 | 8.08% |
| thickness(μm) | | | |
| Standard | 2.11 | 1.17 | 44.5% |
| deviation(%) | | | |

In Table 1, the thickness in the present invention is increased by 8.08%, and the standard deviation of the thickness is improved by 44.5% in comparison with the thickness and the standard deviation of the thickness in the conventional chemical vapor deposition unit. This means that the increase of the growth rate of the thin film can reduce the amount of injected source materials by about 8%.

TABLE 2

| | Conventional | Present | Enhancement |
|---|---|---|---|
| | unit | invention | (%) |
| Standard deviation | 3.671 | 1.317 | 64.1% |
| (nm) | | | |

In Table 2, in comparison with the standard deviation of wavelength in the conventional chemical vapor deposition unit, the standard deviation of wavelength in the chemical vapor deposition unit according to the present invention is enhanced by 64.1%. This means that productivity of the substrate can be enhanced, so that a high quality thin film can be grown. Moreover, since only small amounts of by-products are generated, the time required to remove the by-products in order to perform the next process can be reduced so that productivity is enhanced.

Table 2 shows that the thin film can be grown on tens of substrates at once, and the thickness uniformity of the thin film over all substrates enables mass-production of high quality thin films.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A chemical vapor deposition unit comprising:
a reaction chamber (100) isolated from outside and kept under vacuum,
a susceptor (200) installed in the reacting chamber (100), which is rotatable and on which at least one substrate is placed,
a first gas injecting system including first gas passage (340), first gas injector (370) for independently communicating the first gas through first gas passage and injector to inject the first gas onto the susceptor (200),
a second gas injecting system including second gas passage (350), second gas injector (380) for independently communicating the second gas through second gas passage and injector to inject the second gas onto the susceptor (200),
a set of partitions (310, 320, 330) for forming the first and second gas passages (340, 350) and coolant passage (360), and
an injecting plate (331) with a plurality of first and second gas injecting outlets (331a, 331b) to independently communicate to the susceptor (200), at the central region of the injecting plate (331)), the second gas outlets are arranged for only injecting the second gas (G2), which is a non-reactive carrier gas, to the center region of the susceptor (200).

2. The chemical vapor deposition unit as set forth in claim 1, wherein the second gas region forms a gas chamber (390) at the central region including a central injecting plate (332) with injecting holes (332a) for only injecting the second gas (G2) to the susceptor (200).

3. The chemical vapor deposition unit as set forth in claim 2, wherein said gas injecting part (333) further forms with a protruded bowl-shape with the injecting holes (333a) for smoothly spread the second gas (G2) over the substrate (P).

4. The chemical vapor deposition unit as set forth in claim 2, wherein the susceptor (200) further forms with a guide part (220) for guiding the flow of second gas injected from the gas chamber (390), said guide part (220) located in the central region of the susceptor (200) corresponding to the second gas injecting part (332).
